(19) United States
(12) Patent Application Publication
(10) Pub. No.: US 2017/0198601 A1
(43) Pub. Date: Jul. 13, 2017

(54) INTERNALLY COOLED NI-BASE SUPERALLOY COMPONENT WITH SPALLATION-RESISTANT TBC SYSTEM

(71) Applicant: UNITED TECHNOLOGIES CORPORATION, Hartford, CT (US)

(72) Inventors: Michael N. Task, Vernon, CT (US); Mark A. Boeke, Plainville, CT (US); Jeffrey R. Levine, Vernon Rockville, CT (US); Russell J. Bergman, Windsor, CT (US)

(21) Appl. No.: 14/993,140

(22) Filed: Jan. 12, 2016

(51) Int. Cl. F01D 25/00; C23C 14/16; F01D 9/04; C23C 14/35; C23C 14/30; C22C 19/05; C23C 14/08

(52) U.S. Cl. CPC F01D 25/005; C22C 19/057; C23C 14/16; C23C 14/083; C23C 14/35; C23C 14/30; F01D 9/041; F05D 2300/182; F05D 2300/17; F05D 2300/2118; F05D 2300/611; F05D 2300/175; F05D 2230/21; F05D 2220/32; F05D 2240/128; F05D 2260/231; F05D 2230/312; F05D 2230/313; F05D 2230/90

(57) ABSTRACT

A gas turbine engine component comprising a nozzle segment, the nozzle segment comprising at least one substrate having a surface. A metallic bondcoat is coupled to the surface of the substrate. An yttria-stabilized zirconia thermal barrier coating is coupled to the metallic bondcoat opposite the surface.

### BACKGROUND

Portions of the present disclosure are contained within U.S. Pat. No. 8,641,963, U.S. Patent Publication US 2008/0057195 and U.S. Pat. No. 6,919,042 which are hereby expressly incorporated by reference in its entirety.

The present disclosure particularly relates to a system of combining three technologies of an air cooled nozzle segment, a bond coat, and a thermal barrier coating, that results in a materials system that can be used in the hot section of a gas turbine engine, resulting in a substantial life extension an improved oxidation and fatigue resistant metallic coating for protecting high temperature gas turbine engine components.

Various metallic coatings have been developed in the past for the oxidation protection of high temperature gas turbine engine components. These coatings are often based on different aluminide compositions, and may include nickel or cobalt base metal materials. Alternatively, they are based on overlay deposits with MCrAlY foundations where M is nickel, cobalt, iron or combinations of these materials. These coating systems suffer from shortcomings that preclude their use on newer advanced turbine components. The diffused aluminides, while possessing good fatigue resistance, generally provide lower high temperature oxidation resistance (above 2000 degrees Fahrenheit). The overlay MCrAlY coatings tend to have tensile internal stress, which can promote cracking and reduces the fatigue life of the coating (i.e. creates fatigue debt). The addition of active elements to the MCrAlY coatings not only provides excellent oxidation resistance, but makes them good candidates for bond-coats for thermal barrier coatings.

Thermal barrier coating systems (TBCs) provide a means to protect the turbine engine components from the highest temperatures in the engine. Before a TBCs is applied, metallic bond coats, such as aluminides or MCrAlY coatings, are deposited on the surface of the turbine engine component, and a thermally grown oxide of alumina is grown between the bond coat and the TBCs topcoat.

As superalloy technology advances, the economics and material trade-offs involved in creating creep resistant higher refractory-containing super alloys have become of interest. While both aluminides and MCrAlY coatings have widespread applications, a low-cost improved coating that could combine the best properties from both would have immediate application on advanced turbine components where fatigue, pull weight, and oxidation must all be minimized.

### SUMMARY

In accordance with the present disclosure, there is provided a method for providing a component with a coating system comprising the steps of providing an air cooled component having a substrate; applying a metallic bondcoat to the substrate; and depositing a layer of an yttria-stabilized zirconia thermal barrier coating on the bondcoat.

In another and alternative embodiment, the metallic bondcoat applying step comprises applying a metallic bondcoat selected from the group consisting of a platinum-aluminide coating and an aluminide coating.

In another and alternative embodiment, the metallic bondcoat applying step comprises applying a metallic bondcoat wherein the metallic bondcoat has a composition consisting of 1.0 to 18 wt % cobalt, 3.0 to 18 wt % chromium, 5.0 to 15 wt % aluminum, 0.01 to 1.0 wt % yttrium, 0.01 to 0.6 wt % hafnium, 0.0 to 0.3 wt % silicon, 0.1 to 1.0 wt % zirconium, 0.0 to 10 wt % tantalum, 2.5-5.0 wt % tungsten, 0.0 to 10 wt % molybdenum, 23.0 to 27.0 wt % platinum, and the balance nickel.

In another and alternative embodiment, the yttria-stabilized zirconia coating depositing step comprises depositing a material containing from 4.0 to 25 wt % yttria.

In another and alternative embodiment, the air cooled component providing step comprises providing a substrate formed from a nickel based alloy.

In another and alternative embodiment, the yttria-stabilized zirconia coating depositing step comprises depositing a material consisting of from 4.0 to 25 wt % yttria and the balance zirconia.

In another and alternative embodiment, the air cooled component comprises a nozzle segment.

In another and alternative embodiment, the nozzle segment is selected from the group consisting of a singlet, a doublet and a triplet.

In another and alternative embodiment, the method further comprises installing the air cooled component in a high pressure turbine section of a gas turbine engine.

In accordance with the present disclosure, there is provided a gas turbine engine component comprises a nozzle segment, the nozzle segment comprising at least one substrate having a surface. A metallic bondcoat is coupled to the surface of the substrate. An yttria-stabilized zirconia thermal barrier coating is coupled to the metallic bondcoat opposite the surface.

In another and alternative embodiment, the metallic bondcoat is selected from the group consisting of a platinum-aluminide coating and an aluminide coating.

In another and alternative embodiment, the metallic bondcoat has a composition consisting of 1.0 to 18 wt % cobalt, 3.0 to 18 wt % chromium, 5.0 to 15 wt % aluminum, 0.01 to 1.0 wt % yttrium, 0.01 to 0.6 wt % hafnium, 0.0 to 0.3 wt % silicon, 0.1 to 1.0 wt % zirconium, 0.0 to 10 wt % tantalum, 2.5-5.0 wt % tungsten, 0.0 to 10 wt % molybdenum, 23.0 to 27.0 wt % platinum, and the balance nickel.

In another and alternative embodiment, the yttria-stabilized zirconia coating comprises a material containing from 4.0 to 25 wt % yttria.

In another and alternative embodiment, the yttria-stabilized zirconia coating comprises a material consisting of from 4.0 to 25 wt % yttria and the balance zirconia.

In another and alternative embodiment, the nozzle segment is selected from the group consisting of a singlet, a doublet and a triplet.

In another and alternative embodiment, the nozzle segment is configured air cooled.

Other details of the coating system and process are set forth in the following detailed description and the accompanying drawing wherein like reference numerals depict like elements.

### BRIEF DESCRIPTION OF THE DRAWINGS

FIG. 1 is a schematic representation of a turbine engine component;

FIG. 2. Is a chart of the weight gain per surface area of a first family of coatings 2 and a third family of coatings 4 as they compare to a Re-containing coating of U.S. Pat. No. 6,919,042 2 and the U.S. Pat. No. 6,919,042 Re-containing coating with platinum 3;

FIG. 3 is a schematic representation of a turbine engine component with the disclosed coating system.

### DETAILED DESCRIPTION

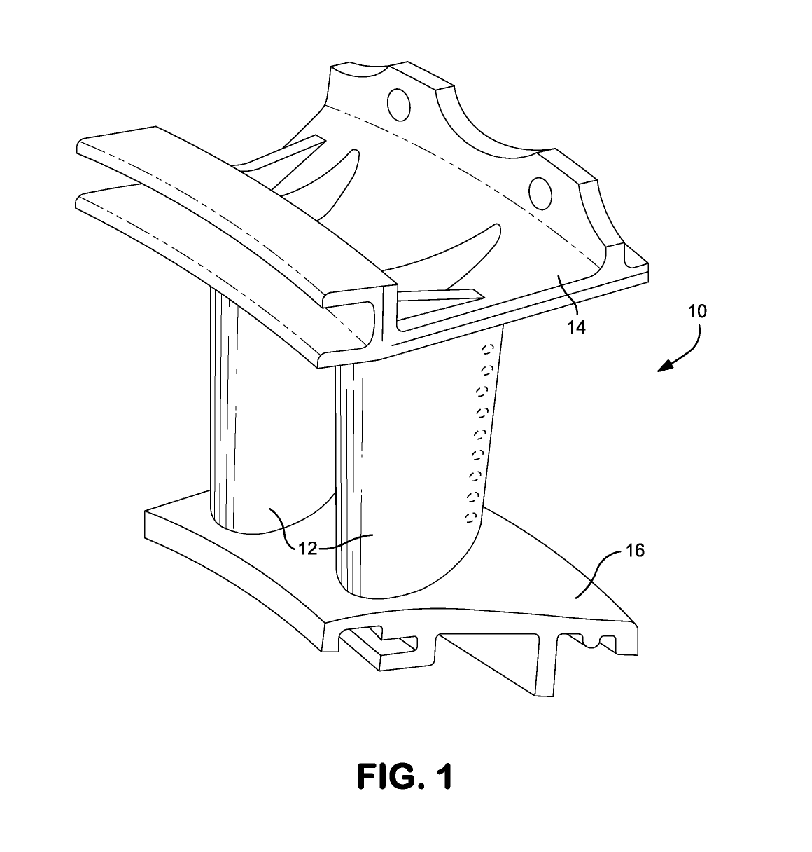

Referring to FIG. 1, a nozzle segment 10 that is one of a number of nozzle segments that when connected together form an annular-shaped nozzle assembly of a gas turbine engine. The segment 10 is made up of multiple vanes 12, each defining an airfoil and extending between outer and inner platforms (bands) 14 and 16. The vanes 12 and platforms 14 and 16 can be formed separately and then assembled, such as by brazing the ends of each vane 12 within openings defined in the platforms 14 and 16.

Alternatively, the entire segment 10 can be formed as an integral casting. When the nozzle segment 10 is assembled with other nozzle segments to form a nozzle assembly, the respective inner and outer platforms of the segments form continuous inner and outer bands between which the vanes 12 are circumferentially spaced and radially extend.

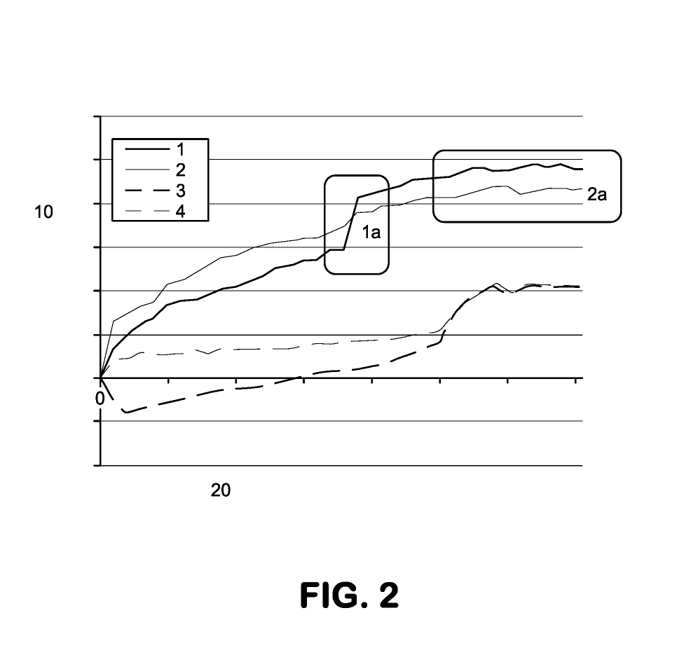

The nozzle segment 10 depicted in FIG. 2 is termed a doublet because two vanes 12 are associated with each segment 10. Nozzle segments can be equipped with more than two vanes, e.g., three (termed a triplet), or with a single vane to form what is termed a singlet.

The air-cooled nozzle segments of the high pressure turbine (HPT) stage 2 nozzle assembly of the gas turbine engine are cast from the nickel-base super alloy.

As a result of being located in the high pressure turbine section of the engine, the vanes 12 and the surfaces of the platforms 14 and 16 facing the vanes 12 are subjected to the hot combustion gases from the engine's combustor. As previously noted, in addition to forced air cooling techniques, the surfaces of the vanes 12 and platforms 14 and 16 are typically protected from oxidation and hot corrosion with an environmental coating, which may then serve as a bond coat to a TBC deposited on the surfaces of the vanes 12 and platforms 14 and 16 to reduce heat transfer to the segment 10.

Turbine engine components are formed from nickel-based, cobalt-based, and iron-based alloys. Due to the extreme high temperature environments in which these components are used, it is necessary to provide them with a protective coating. Metallic bond coatings must have a composition which minimizes the fatigue impact on the turbine engine components to which they are applied and at the same time provides maximum oxidation resistance properties. The coating must also be one where the thermal expansion mismatch between the coating and the alloy(s) used to form the turbine engine components is minimized. This mismatch is a cause of fatigue performance of MCrAlY coatings.

In accordance with the present disclosure, low-cost metallic coatings have been developed which reduce the thermal mismatch and which provide a good oxidation and fatigue resistance. The coatings can be used as stand-alone bond coat or as a bond coat used within a TBC system. These metallic coatings have a composition which broadly consists of 1.0 to 18 wt % cobalt, 3.0 to 18 wt % chromium, 5.0 to 15 wt % aluminum, 0.01 to 1.0 wt % yttrium, 0.01 to 0.6 wt % hafnium, 0.0 to 0.3 wt % silicon, 0.0 to 1.0 wt % zirconium, 0.0 to 10 wt % tantalum, 0.0 to 9.0 wt % tungsten, 0.0 to 10 wt % molybdenum, 0.0 to 43.0 wt % platinum, and the balance nickel.

Within the foregoing broad scope of coating compositions, a first family of particularly useful coatings for turbine engine components has a composition which consists of 1.0 to 15 wt %, for example 10.0 wt % cobalt, 5.0 to 18 wt %, for example 5.0 wt % chromium, 5.0 to 12 wt %, for example 11.0 wt % aluminum, 0.01 to 1.0 wt %, for example 0.6 wt % yttrium, 0.01 to 0.6 wt %, for example 0.6 wt % hafnium, 0.0 to 0.3 wt %, for example 0.2 wt % silicon, 0.0 to 1.0 wt %, for example 0.1 wt % zirconium, 3.0 to 10 wt %, for example 3.0 to 6.0 wt % tantalum, 0.0 to 5.0 wt %, for example 2.5 to 5.0 wt % tungsten, 0.0 to 10 wt %, for example 2.0 wt % or less molybdenum, and the balance nickel. The total combined amount of tantalum and tungsten in these metallic coatings is in the range of 3.0 to 12 wt % and for example in the range of 5.5 to 11.0 wt %.

Within this first family of coatings, a particularly useful coating composition consists of 10.0 wt % cobalt, 5.0 wt % chromium, 11.0 wt % aluminum, 0.6 wt % yttrium, 0.6 wt % hafnium, 0.2 wt % silicon, 0.1 wt % zirconium, 3.0 to 6.0 wt % tantalum, 2.5 to 5.0 wt % tungsten, 0.8 to 1.7 wt % molybdenum, and the balance nickel.

For somewhat slower oxidation kinetics, a second family of particularly useful metallic coating compositions comprises 1.0 to 15 wt %, for instance 10.0 wt % cobalt, 5.0 to 18 wt %, for instance 5.0 wt % chromium, 5.0 to 12 wt %, for instance 11.0 wt % aluminum, 0.01 to 1.0 wt %, for example 0.6 wt % yttrium, 0.01 to 0.6 wt %, for example 0.6 wt % hafnium, 0.0 to 0.3 wt %, for example 0.2 wt % silicon, 0.0 to 1.0 wt %, for example 0.1 wt % zirconium, and the balance nickel. This second family of metallic coating may also contain 0.0 to 43.0% platinum and is devoid of all refractory metals, i.e. tungsten, molybdenum, tantalum, niobium and rhenium. These refractory elements are known to provide strength to superalloy materials; however, they are not known to possess oxidation resistant properties, they are expensive and at higher levels they promote topologically close packed phases.

Within this second family of coatings, a particularly useful coating composition consists of about 10.0 wt % cobalt, 5.0 wt % chromium, 11.0 wt % aluminum, 0.6 wt % yttrium, 0.6 wt % hafnium, 0.2 wt % silicon, 0.1 wt % zirconium, and the balance nickel.

A third family of particularly useful coatings for turbine engine components has a composition which consists of 1.0 to up to about 15 wt %, for example 10.0 wt % cobalt, 5.0 to 18 wt %, for example 5.0 wt % chromium, 5.0 to 12 wt %, for example 11.0 wt % aluminum, 0.01 to 1.0 wt %, for example 0.6 wt % yttrium, 0.01 to 0.6 wt %, for example 0.6 wt % hafnium, 0.0 to 0.3 wt %, for example 0.2 wt % silicon, 0.0 to 1.0 wt %, for example 0.1 wt % zirconium, 3.0 to 10 wt %, for example 3.0 to 6.0 wt % tantalum, 0.0 to 5.0 wt %, for example 2.5 to 5.0 wt % tungsten, 0.0 to 10 wt %, for example 2.0 wt % or less molybdenum, 10.0 to 43.0 wt %, for example 23.0 to 27.0 wt % platinum and the balance nickel. The total combined amount of tantalum and tungsten in these metallic coatings is in the range of 3.0 to 12 wt % and for example in the range of 5.5 to 11.0 wt %.

Within this third family of coatings, a particularly useful coating composition consists of 8.0 wt % cobalt, 4.0 wt % chromium, 9.0 wt % aluminum, 5.0 wt % tantalum, 1.0 wt % molybdenum, 4.0 wt % tungsten, 0.6 wt % yttrium, 0.6 wt % hafnium, 0.2 wt % silicon, 0.1 wt % zirconium, and about 23.0 to about 27.0 wt % platinum.

FIG. 2 charts the weight gain per surface area of the first family of coatings 2 and the third family of coatings 4 as they compare to the Re-containing coating of U.S. Pat. No. 6,919,042 and the U.S. Pat. No. 6,919,042 Re-containing coating with platinum 3. The oxide growth is measured by weight gain per surface area (Δm/A, (mg/cm²)) 10 on the y-axis versus the number of 60 minute cycles 20 on the x-axis. The 60 minute cycles are hot/cold cycles consisting of 52 minutes at a temperature of about 2085° F. to 2115° F. and 8 minutes cooling to a temperature of approximately 212° F. The oxide growth kinetics are measured as a function of time. Slower weight gain results in better oxide growth, i.e. oxidation kinetics.

U.S. Pat. No. 6,919,042 Re containing coating 1, FIG. 2 displays parabolic mass gain/surface area for the initial stages of oxidation; however, following additional exposure, e.g., greater than nominally 350 cycles at 2100° F. Region 1 a, the oxidation behavior of the composition experiences a large mass gain. Compared with coating 2, a non-Re containing embodiment from the first family of coatings, the mass gain/surface area with time is much more uniform with little deviation from its parabolic features. Further, at exposures greater than 400 cycles Region 2 a, the predominately parallel curves of coating 1 and coating 2 shows that the oxidation rates are similar; however, the mass gain of coating 2 appears kinetically more favorable than coating 1.

In FIG. 2, the Pt-containing embodiments of the present invention, 3 and 4, exhibit slower oxidation kinetics than their non-Pt containing counterparts, and thus, appear more favorable from a long term oxidation resistance point of view. The Re-containing coating according to U.S. Pat. No. 6,919,042, with platinum 3, shows an initial mass loss. The initial mass loss is suspected to be due to the Pt plating process, e.g. some of the Pt was not fully adhered. As compared to coating with platinum 4, Re-containing coating 3 gains weight at a faster rate. While the oxidation behavior at the onset of testing is not straightforward, it was observed that the overall oxidation rate is quite favorable.

A driver of poor coating fatigue performance is excessive coating thickness. Coatings with the aforesaid compositions may have a thickness of 1 to 10 mils (0.001 to 0.01 inch), for example 1 to 2 mils (0.001 to 0.002 inch). Typical methods of depositing overlay coatings include thermal spray techniques such as low pressure plasma spray (LPPS), which creates coating thicknesses in the range of 4 to 12 mils (0.004 to 0.012 inch). Using cathodic arc plasma vapor deposition techniques, it is possible to apply coatings with the aforesaid compositions having a thickness of 2 mils (0.002 inch) or thinner. Techniques for applying the coatings of the present disclosure by cathodic arc plasma vapor deposition are discussed in U.S. Pat. Nos. 5,972,185; 5,932,078; 6,036,828; 5,792,267; and 6,224,726, all of which are incorporated by reference herein. Alternate methods of deposition, including other plasma vapor deposition techniques such as magnetron sputtering and electron beam plasma vapor deposition may be used. When thickness concerns are not present, various thermal spray techniques such as low pressure plasma spray and HVOF (high velocity oxy-fuel) techniques may be utilized.

For example, the third family of coatings containing Pt may be deposited by various coating methods, such as the coating methods detailed above, various coating methods within the art and/or additional methods. For instance, it is possible to deposit the Pt after the non-Pt portion of the coating is deposited via a cathodic arc plasma technique or a LPPS technique. In this coating example, the Pt is deposited over the top of the pre-deposited coating via plating, EB-PVD, sputtering or some other physical vapor deposition (PVD) method. The Pt is then diffused into the coating. The Pt may also be deposited prior to the non-Pt PVD coating process. In this instance, the bond coat is deposited on top of the Pt interlayer and then subjected to a diffusion heat treatment. Alternatively, Pt may be incorporated into the coating source material and deposited via conventional aforementioned PVD methods.

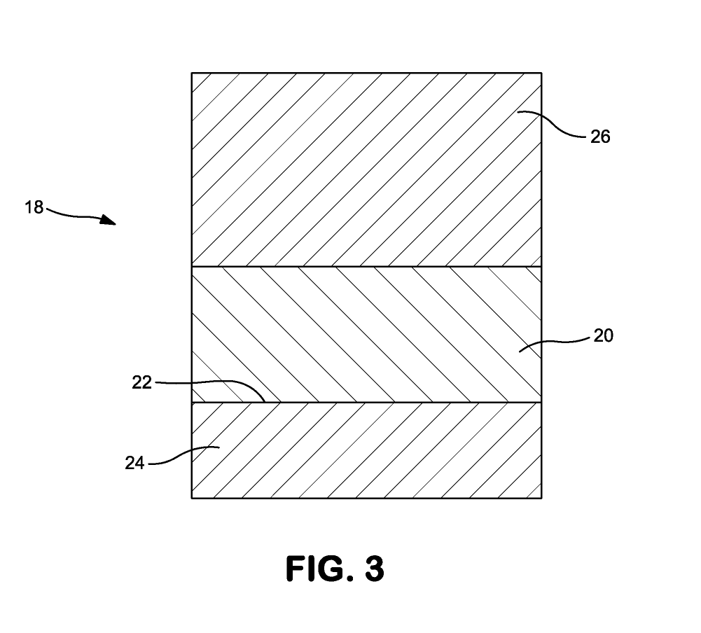

Referring now to FIG. 3, a coating system 18 includes a bond coat 20 applied to a surface 22 of a substrate 24, such as a turbine engine component including, but not limited to, a blade or a vane 12 as described above. The bond coat 20 can comprise the low-cost metallic coatings described above. The coatings can be used as the bond coat used within a coating system 18. A thermal barrier coating (TBC) 26 is coupled to the bond coat 20. The thermal barrier coating 26 can comprise metallic coatings that have a composition of yttria-stabilized zirconia.

The substrate 24 may be formed from any suitable material such as a nickel based superalloy, a cobalt based alloy, a molybdenum based alloy or a titanium alloy. The substrate 24 may or may not be coated with a metallic bondcoat 20 (as described above). In alternative embodiments suitable metallic bondcoats 20 which may be used include diffusion bondcoats, such as platinum-aluminide coating or an aluminide coating, or MCrAlY coatings where M is at least one of nickel, cobalt, and iron. The bondcoat 20 may have any desired thickness.

The TBC 26 can consist of a single layer, two layer, or three layer ceramic coating.

These layers can be yttria-stabilized zirconia (YSZ), rare earth zirconates, or combinations of the two.

The yttria-stabilized zirconia thermal barrier coating 26 may be applied by, for example, electron beam physical vapor deposition (EB-PVD) or air plasma spray. Other methods which can be used to deposit the yttria stabilized zirconia thermal barrier coating 26 includes, but is not limited to, sol-gel techniques, slurry techniques, sputtering techniques, and chemical vapor deposition techniques.

The method of application may also include a variation of the EBPVD process which allows TBC to be deposited in hidden areas of the vane doublet (the “Non-Line-of-Site” process).

A preferred process for performing the deposition of the yttria-stabilized zirconia thermal barrier coating 26 is EB-PVD. When performing this process, the substrate 24 is placed in a coating chamber and heated to a temperature in the range of from 1700 to 2000 degrees Fahrenheit. The coating chamber is maintained at a pressure in the range of from 0.1 to 1.0 millitorr. The feedstock feed rate is from 0.2 to 1.5 inches/hour. The coating time may be in the range of from 20 to 120 minutes.

The deposited coating 26 may have a thickness of from 3.0 to 50 mils, preferably from 5.0 to 15 mils. The deposited coating 26 may have a yttria content in the range of from 4.0 to 25 wt %, preferably from 6.0 to 9.0 wt %. The deposited coating 26 may consist of yttria in the amount of 4.0 to 25 wt % and the balance zirconia. In a more preferred embodiment, the deposited coating 26 may consist of yttria in the amount of 6.0 to 9.0 wt % yttria and the balance zirconia.

The disclosed materials system is capable of providing cooled turbine hardware with extended TBC spallation life. This will be beneficial for any hot section component in legacy and next generation engines that relies on a thermal barrier coating.

TBC spallation resistance superior to legacy MCrAlY-type bond coat/ EBPVD systems is achieved by combining a single crystal Ni-base superalloy material with the disclosed advanced bond coat and the EBPVD thermal barrier coating.

The use of the disclosed advanced bond coat has a gamma/gamma prime structure, in contrast to traditional gamma/beta coatings, and provides a significant increase in ceramic spallation life. More modest, yet significant, increases in bond coat oxidation life have also been measured in laboratory testing.

Increased TBC spallation and bond coat oxidation life allow for extended time on wing in aggressive environments. The result is an increase in HSRI and reduced maintenance cost relative to legacy materials systems, as described above.

Combining all three of the described technologies; nozzle segment, bond coat, and thermal barrier coating, results in a materials system that can be used in the hot section of a gas turbine engine, resulting in a substantial life extension.

It is apparent that there has been provided in accordance with the present disclosure a cooled component with a coating system having a thermal barrier coating and a low-cost oxidation and fatigue resistant metallic coating which fully satisfies the embodiments set forth hereinbefore. While the present disclosure has been described in the context of specific coatings thereof, other alternatives, modifications, and variations will become apparent to those skilled in the art having read the foregoing description. Accordingly, it is intended to embrace those alternatives, modifications, and variations as they fall within the broad scope of the appended claims.

What is claimed is:

1. A method for providing a component with a coating system comprising the steps of:
providing an air cooled component having a substrate;
applying a metallic bondcoat to said substrate; and
depositing a layer of an yttria-stabilized zirconia thermal barrier coating on the bondcoat.

2. The method according to claim 1, wherein said metallic bondcoat applying step comprises applying a metallic bondcoat selected from the group consisting of a platinum-aluminide coating and an aluminide coating.

3. The method according to claim 2, wherein said metallic bondcoat applying step comprises applying a metallic bondcoat wherein said metallic bondcoat has a composition consisting of 1.0 to 18 wt % cobalt, 3.0 to 18 wt % chromium, 5.0 to 15 wt % aluminum, 0.01 to 1.0 wt % yttrium, 0.01 to 0.6 wt % hafnium, 0.0 to 0.3 wt % silicon, 0.1 to 1.0 wt % zirconium, 0.0 to 10 wt % tantalum, 2.5-5.0 wt % tungsten, 0.0 to 10 wt % molybdenum, 23.0 to 27.0 wt % platinum, and the balance nickel.

4. The method according to claim 1, wherein said yttria-stabilized zirconia coating depositing step comprises depositing a material containing from 4.0 to 25 wt % yttria.

5. The method according to claim 1, wherein said air cooled component providing step comprises providing a substrate formed from a nickel based alloy.

6. The method according to claim 1, wherein said yttria-stabilized zirconia coating depositing step comprises depositing a material consisting of from 4.0 to 25 wt % yttria and the balance zirconia.

7. The method according to claim 1, wherein said air cooled component comprises a nozzle segment.

8. The method of claim 7, wherein said nozzle segment is selected from the group consisting of a singlet, a doublet and a triplet.

9. The method of claim 1, further comprising:
installing said air cooled component in a high pressure turbine section of a gas turbine engine.

10. A gas turbine engine component comprising:
a nozzle segment, said nozzle segment comprising at least one substrate having a surface;
a metallic bondcoat coupled to said surface of said substrate; and
an yttria-stabilized zirconia thermal barrier coating coupled to said metallic bondcoat opposite said surface.

11. The gas turbine engine component according to claim 10, wherein said metallic bondcoat is selected from the group consisting of a platinum-aluminide coating and an aluminide coating.

12. The gas turbine engine component according to claim 10, wherein said metallic bondcoat has a composition consisting of 1.0 to 18 wt % cobalt, 3.0 to 18 wt % chromium, 5.0 to 15 wt % aluminum, 0.01 to 1.0 wt % yttrium, 0.01 to 0.6 wt % hafnium, 0.0 to 0.3 wt % silicon, 0.1 to 1.0 wt % zirconium, 0.0 to 10 wt % tantalum, 2.5-5.0 wt % tungsten, 0.0 to 10 wt % molybdenum, 23.0 to 27.0 wt % platinum, and the balance nickel.

13. The gas turbine engine component according to claim 10, wherein said yttria-stabilized zirconia coating comprises a material containing from 4.0 to 25 wt % yttria.

14. The gas turbine engine component according to claim 10, wherein said yttria-stabilized zirconia coating comprises a material consisting of from 4.0 to 25 wt % yttria and the balance zirconia.

15. The gas turbine engine component according to claim 10, wherein said nozzle segment is selected from the group consisting of a singlet, a doublet and a triplet.

16. The gas turbine engine component according to claim 10, wherein said nozzle segment is configured air cooled.
